(19) United States
(12) Patent Application Publication
(10) Pub. No.: US 2010/0209741 A1
(43) Pub. Date: Aug. 19, 2010

(54) PERPENDICULAR MAGNETIC RECORDING MEDIUM, PROCESS FOR PRODUCTION THEREOF, AND MAGNETIC RECORDING/REPRODUCTION APPARATUS

(75) Inventors: Yuzo Sasaki, Ichihara-shi (JP); Atsushi Hashimoto, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/670,815

(22) PCT Filed: Jul. 25, 2008
(86) PCT No.: PCT/JP2008/063374

§ 371 Date: Apr. 29, 2010

(30) Foreign Application Priority Data
Jul. 26, 2007 (JP) 2007-194038

(51) Int. Cl. G11B 5/706; C23C 14/34

(52) U.S. Cl. 428/846.8; 428/846.6; 428/846.7; 204/192.2

(57) ABSTRACT

A perpendicular magnetic recording medium is provided, which has a soft magnetic layer, an under layer, an intermediate layer and a perpendicular magnetic recording layer, and is characterized in that the perpendicular magnetic recording layer is comprised of at least one magnetic layer, which magnetic layer or at least one of which magnetic layers comprises cobalt-based ferromagnetic crystal grains and grain boundaries comprised of an oxide, wherein the ferromagnetic crystal grains further comprise ruthenium. The perpendicular magnetic recording medium has ferromagnetic crystal grains with extremely small grain size and exhibiting enhanced discretion, as well as good perpendicular orientation in the perpendicular magnetic recording layer, and thus, the medium is capable of recording and reproducing information with high density.

### TECHNICAL FIELD

This invention relates to a magnetic recording medium, a process for producing the magnetic recording medium, and a magnetic recording reproducing apparatus provided with the magnetic recording medium.

### BACKGROUND ART

In recent years, magnetic recording apparatuses such as a magnetic disk apparatus, a flexible disk apparatus and a magnetic tape apparatus are widely used and their importance is increasing. Recording density of a magnetic recording medium provided with the magnetic recording apparatuses is greatly enhanced. Especially, since the development of an MR head and a PRML technique, the areal recording density is more and more increasing. Recently a GMR head and a TuMR head have been developed, and the rate of increase in the areal recording density is about 100% per year.

There is still increasing a demand for further enhancing the recording density in magnetic recording media, and therefore, a magnetic layer having a higher coercive force and a higher signal-to-noise ratio (SNR), and a higher resolution are eagerly desired.

In longitudinal magnetic recording media heretofore widely used, a self-demagnetization effect becomes significantly manifested, that is, adjacent magnetic domains in magnetic transition regions exhibit a function of counteracting the magnetization each other with an increase in a line recording density. To minimize the self-demagnetization effect, thickness of the magnetic recording layer must be reduced to enhance the shape magnetic anisotropy.

However, with a decrease in thickness of the magnetic recording layer, the magnitude of energy barrier for keeping the magnetic domains approximates to the magnitude of heat energy, and consequently, the heat fluctuation occurs, i.e., the recorded magnetization is reduced by the influence of the temperature. This undesirable phenomenon is said to put an upper limit on the line recordation density.

Recently, an anti-ferromagnetic coupling (AFC) medium has been proposed as means for solving the problem of limitation in the line magnetic recording density in the longitudinal magnetic recording media, which problem arises due to the alleviation of magnetization upon heating.

Perpendicular magnetic recording media attract widespread attention as means for enhancing the plane magnetic recording density. The perpendicular magnetic recording media are characterized in that the magnetization occurs in a direction perpendicular to the major surface of the magnetic recording media, which is in a contrast to the transitional longitudinal magnetic recording media wherein the magnetization occurs in an in-plane direction. Due to this characteristic, the undesirable magnetization-counteracting function as encountered as an obstacle for enhancing the line recording density in the longitudinal magnetic recording media can be avoided, and the magnetic recording density can be more enhanced. Further, the thickness of magnetic recording layer can be maintained at a certain level, and thus, the problem of alleviation of magnetization upon heating as encountered in the traditional longitudinal magnetic recording media can be minimized.

In the manufacture of perpendicular magnetic recording media, an under layer, an intermediate layer, a magnetic recording layer and an overcoat are usually formed in this order on a non-magnetic substrate. Further, a lubricating layer is often formed on the uppermost overcoat. In many magnetic recording media, a magnetic layer called as a soft magnetic layer is formed beneath the under layer. The under layer and the intermediate layer are formed for the purpose of improving the characteristics of the magnetic recording layer, more specifically, for providing desired crystal orientation and controlling the shape of magnetic crystals in the magnetic recording layer.

To produce perpendicular magnetic recording media having a high recording density and improved magnetic characteristics, the crystalline structure of the magnetic recording layer, the discretion or decoupling of crystal grains and the refinement of grain diameter are important. In perpendicular magnetic recording media, the crystalline structure in the magnetic recording layer is often a hexagonal close-packed (hcp) structure. In this crystalline structure, the (002) crystal plane is parallel to the substrate surface, that is, the crystalline c-axes (i.e., [002] axes) are arranged in the perpendicular direction with minimized disturbance, and thus, the intensity of a signal given in the perpendicular direction increases. Further, when crystal grains in the magnetic recording layer become more discrete and the exchange coupling is interrupted, a noise at reproduction from the high density recording can be minimized.

As material for the magnetic recording layer, alloy targets such as, for example, CoCrPt, which have been combined with silicon oxide and/or titanium oxide, have been used (see, for example, patent document 1, below).

The magnetic recording layer formed using such alloy target has a granular structure wherein CoCrPt crystal grains having a hcp structure are surrounded by grain boundaries comprised of non-magnetic silicon oxide and/or titanium oxide. In this granular structure, good crystal orientation and good refinement of crystal grains and discretion of crystal grains can be achieved. Silicon and titanium incorporated as grain boundary material in the cobalt magnetic material exhibit a larger free energy change for oxidation than the cobalt magnetic material, and therefore, oxides of these elements suppress the undesirable oxidation of cobalt (i.e., prevent or minimize the deterioration of magnetic property) (see, for example, patent document 2, below).

Therefore silicon oxide and titanium oxide have a function of suppressing oxidation of cobalt and thus preventing the decrease of the magnetic moment. However, silicon oxide and titanium oxide, incorporated in CoCrPt grains, exert an undesirable influence on the orientation of the magnetic crystal grains and the discretion of magnetic crystal grains, with the result of increase in noise.

Thus, in order to provide a magnetic recording medium having more improved recording and reproducing characteristics, it is necessary that discretion of magnetic crystal grains and refinement of crystal grain diameter, and perpendicular orientation are more enhanced. Thus, such magnetic recording medium having more improved recording and reproducing characteristics, which can be easily produced, is eagerly desired.

Patent document 1: JP 2004-327006 A

Patent document 2: JP 2006-164440 A

### DISCLOSURE OF THE INVENTION

### Problems to be Solved by the Invention

In view of the foregoing background art, a primary object of the present invention is to provide a magnetic recording medium characterized as exhibiting enhanced discretion or decoupling of magnetic crystal grains and enhanced refinement of crystal grain diameter, as well as good perpendicular orientation in the perpendicular magnetic recording layer, and thus, characterized as being capable of recording and reproducing information with high density.

Another object of the present invention is to provide a process for producing the magnetic recording medium having the above-mentioned beneficial characteristics.

A further object of the present invention is to provide a magnetic recording reproducing apparatus provided with a magnetic recording medium having the above-mentioned beneficial characteristics.

### Means for Solving the Problems

In accordance with the present invention, there are provided the following magnetic recording medium, the following process for producing the magnetic recording medium, and the following magnetic recording reproducing apparatus.

(1) A perpendicular magnetic recording medium comprising at least a soft magnetic layer, an under layer, an intermediate layer and a perpendicular magnetic recording layer, which are formed on a non-magnetic substrate, characterized in that said perpendicular magnetic recording layer is comprised of at least one magnetic layer, which magnetic layer or at least one of which magnetic layers comprises ferromagnetic crystal grains predominantly comprised of cobalt and grain boundaries comprised of an oxide, wherein said ferromagnetic crystal grains further comprise ruthenium.

(2) The perpendicular magnetic recording medium as mentioned above in (1), wherein the content of ruthenium in the ferromagnetic crystal grains is in the range of 1 atomic % to 15 atomic %.

(3) The perpendicular magnetic recording medium as mentioned above in (1) or (2), wherein the oxide contained in the magnetic layer or layers comprising the ferromagnetic crystal grains and the grain boundaries comprised of an oxide is at least one oxide selected from the group consisting of oxides of Si, Ti, Ta, Cr, Al, W, Nb and Ru.

(4) The perpendicular magnetic recording medium as mentioned above in any one of (1) to (3), wherein the total amount of the oxide contained in the magnetic layer or layers comprising the ferromagnetic crystal grains and the grain boundaries comprised of an oxide is in the range of 2% to 20% by mole.

(5) The perpendicular magnetic recording medium as mentioned above in anyone of (1) to (4), wherein the ferromagnetic crystal grains have an average grain diameter in the range of 3 nm to 12 nm.

(6) The perpendicular magnetic recording medium as mentioned above in any one of (1) to (5), wherein the thickness of the magnetic layer or each of the magnetic layers, which comprises the ferromagnetic crystal grains and the grain boundaries comprised of an oxide, is in the range of 1 nm to 20 nm; and the total thickness of the magnetic layers is in the range of 2 nm to 40 nm.

(7) The perpendicular magnetic recording medium as mentioned above in any one of (1) to (6), wherein the soft magnetic layer has a soft magnetic non-crystalline or microcrystalline structure.

(8) A process for producing the perpendicular magnetic recording medium as mentioned above in any one of (1) to (7), which comprises a step of forming the perpendicular magnetic recording layer by sputtering a target material which comprises a ferromagnetic material comprising at least cobalt, and an oxide material, wherein at least one of the ferromagnetic material and the oxide material contains ruthenium.

(9) A magnetic recording reproducing apparatus provided with a perpendicular magnetic recording medium and a magnetic head for recording and reproducing an information in the magnetic recording medium, characterized in that the perpendicular magnetic recording medium is the one as mentioned above in any one of (1) to (7).

### EFFECT OF THE INVENTION

According to the present invention, there is provided a perpendicular magnetic recording medium, which has a perpendicular magnetic recording layer wherein the crystal c-axis in a hcp structure is oriented perpendicularly to the surface of substrate with a minimized angle variation, and the ferromagnetic crystal grains constituting the perpendicular magnetic recording layer have an extremely small average grain diameter, and which exhibits highly enhanced recording density characteristic.

### BRIEF DESCRIPTION OF THE DRAWINGS

FIG. 1 is a cross-section illustrating one example of a perpendicular magnetic recording medium according to the present invention.

FIG. 2 is a schematic illustration of an example of the magnetic recording-reproducing apparatus according to the present invention.

### REFERENCE NUMERALS

1 Non-magnetic substrate
2 Soft magnetic layer
3 Under layer
4 Intermediate layer
5 Perpendicular magnetic recording layer
6 Overcoat
10 Magnetic recording medium
11 Medium-driving part
12 Magnetic head
13 Head driving part
14 Recording-reproducing signal system

### BEST MODE FOR CARRYING OUT THE INVENTION

The invention will now be described more specifically with reference to the accompanying drawings.

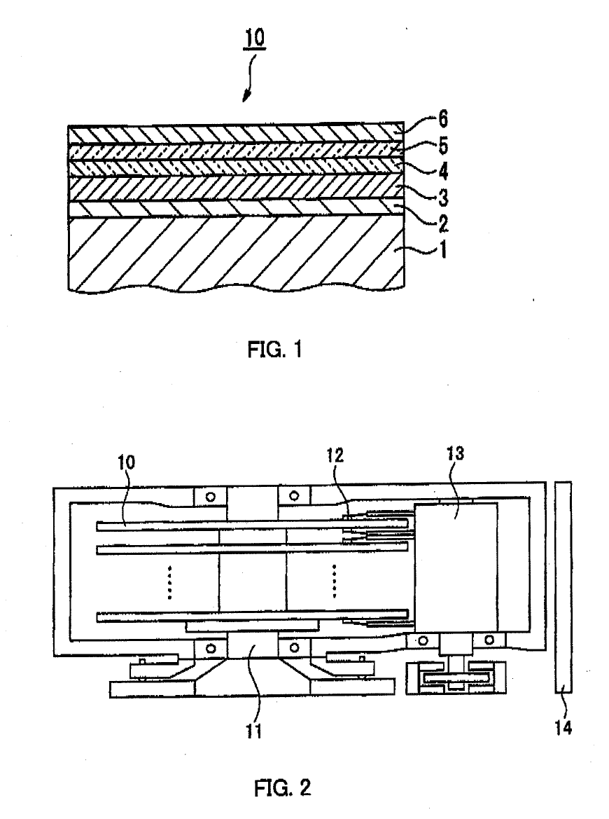

As illustrated in FIG. 1, the perpendicular magnetic recording medium 10 (which is hereinafter referred to as “magnetic recording medium” when appropriate) according to the present invention has a multilayer structure comprising at least a soft magnetic layer 2; an under layer 3 and an intermediate layer 4, which constitute an orientation-controlling layer having a function of controlling orientation in a layer formed thereon; and a perpendicular magnetic recording layer 5 (which is hereinafter referred to as “magnetic recording layer” when appropriate), wherein the axis of easy magnetization (i.e., crystal c-axis) is orientated in a direction approximately perpendicular to the surface of substrate 1; and an optional the overcoat 6; which are formed in this order on the substrate 1.

The perpendicular magnetic recording layer 5 is comprised of at least one magnetic layer, which magnetic layer or at least one of which magnetic layers has a granular structure comprising ferromagnetic crystal grains and grain boundaries comprised of a non-magnetic oxide.

The non-magnetic substrate used in the magnetic recording medium according to the present invention is not particularly limited provided that it is comprised of a non-magnetic material, and, as specific examples thereof, there can be mentioned aluminum alloy substrates predominantly comprised of aluminum such as, for example, an Al—Mg alloy substrate; and substrates made of ordinary soda glass, aluminosilicate glass, amorphous glass, silicon, titanium, ceramics, sapphire, quartz and resins. Of these, aluminum alloy substrates and glass substrates such as crystallized glass substrates and amorphous glass substrate are widely used. As the glass substrates, mirror polished glass substrates and low surface roughness (Ra) glass substrates, for example, those having Ra<1 angstrom, are preferably used. The substrates may be textured to some extent.

In the process for producing the magnetic recording medium, the substrate is usually washed and then dried. That is, the substrates are washed and then dried for assuring sufficient interlayer adhesion. The washing can be conducted with water. Etching (i.e., reverse sputtering) may also be adopted for washing. The size of the substrates is not particularly limited.

The respective layers of the magnetic recording medium will be explained.

The soft magnetic layer is widely provided in many perpendicular magnetic recording media. The soft magnetic layer has a function of, when a signal is recorded in the magnetic recording medium, conducting recording magnetic field from a head and imposing a perpendicular magnetic recording field to a magnetic recording layer in the magnetic recording medium with enhanced efficiency.

The material for the soft magnetic layer is not particularly limited provided it has a soft magnetic property, and, as specific examples thereof, there can be mentioned FeCo alloys, CoZrNb alloys and CoTaZr alloys.

The soft magnetic layer preferably has an amorphous or microcrystalline structure because the surface roughness (Ra) is reduced and thus lift-up of a head is minimized, thereby more improving the recording density characteristics.

The soft magnetic layer may be either a single layer or a multi-layer comprised of two or more layers. One example thereof has a multi-layer structure wherein an extremely thin film of non-magnetic material such as Ru is sandwiched between two soft magnetic layers, i.e., an anti-ferromagnetically coupled (AFC) layer with a Ru spacer layer.

The total thickness of the soft magnetic layer or layers is appropriately determined depending upon the balance between the recording/reproducing characteristics of the magnetic recording layer and the OW characteristics thereof, but the total thickness of the soft magnetic layer or layers is usually in the range of about 20 nm to 120 nm.

An orientation control layer having a function of controlling the orientation of the magnetic recording layer is formed on the soft magnetic layer in the perpendicular magnetic recording medium of the invention. The orientation control layer has a multi-layer structure which comprises an under layer, and an intermediate layer, formed in this order on the soft magnetic layer.

The under layer is comprised of, for example, tantalum, or metal or metal alloys having a fcc structure capable of being oriented in the (111) crystal plane, such as, for example, Ni, Ni—Nb, Ni—Ta, Ni—V, Ni—W, NiFe and Pt.

Even in the case when the soft magnetic layer has an amorphous or microcrystalline structure, the surface roughness (Ra) is sometimes increased depending upon the material for the soft magnetic layer, and the soft magnetic layer-forming conditions, and therefore, a non-magnetic amorphous layer can be formed between the soft magnetic layer and the orientation control layer to reduce Ra and improve the crystal orientation in the magnetic recording layer.

The intermediate layer formed on the under layer is comprised of a material preferably having a hcp structure in a fashion similar to the magnetic recording layer, which material is usually selected from Ru and Re, and their alloys. The intermediate layer is provided for the purpose of controlling the orientation in the magnetic recording layer, and therefore, even if the material does not have a hcp structure, it can be used provided that it is capable of controlling the orientation in the magnetic recording layer.

The perpendicular magnetic recoding layer in the magnetic recording medium according to the invention has a granular structure. Therefore, the intermediate layer preferably has a rough surface, which is obtained by conducting the formation of intermediate layer at a high gas pressure. However, adoption of too high gas pressure leads to deterioration of crystal orientation of the intermediate layer and sometimes results in an intermediate layer having a too high surface roughness. Therefore, to satisfy both of the crystal orientation and the surface roughness, the optimal gas pressure should preferably be chosen, or a double-layered intermediate layer comprising a layer formed at a low gas pressure and a layer formed at a high gas pressure should preferably be provided.

The perpendicular magnetic recording layer is provided for recording a signal thereon.

The perpendicular magnetic recording layer in the magnetic recording medium of the invention is comprised of at least one magnetic layer. The magnetic layer or at least one of the magnetic layers has a granular structure comprising ferromagnetic crystal grains which are predominantly comprised of cobalt and further contain ruthenium, and further comprising grain boundaries comprised of an oxide.

As specific examples of the ferromagnetic material in the perpendicular magnetic recording layer, there can be mentioned cobalt-based alloys such as CoCrPtRu, CoCrRu, CoCrPtRuB, CoPtRu, CoPtRuB and CoCrRuB.

The oxide for grain boundaries in the granular structure is preferably at least one oxide selected from the group consisting of oxides of Si, Ti, Ta, Cr, Al, W, Nb and Ru.

The total amount of the oxide or oxides contained in the magnetic layer or layers comprising the ferromagnetic crystal grains, which are predominantly comprised of cobalt and further contain ruthenium, and further comprising the grain boundaries comprised of the oxide is preferably in the range of 2% to 20% by mole.

The perpendicular magnetic recording layer comprised of at least one magnetic layer is characterized in that the magnetic layer or at least one of the magnetic layers comprises ferromagnetic crystal grains which are predominantly comprised of cobalt and further comprise ruthenium. The content of ruthenium in the ferromagnetic crystal grains is preferably in the range of 1 atomic % to 15 atomic %.

The thickness of the magnetic layer or each of the magnetic layers is preferably in the range of 1 nm to 20 nm. The ferromagnetic crystal grains have an average grain diameter preferably in the range of 3 nm to 12 nm. The average grain diameter can be measured on the plane-view TEM images.

As mentioned above, the perpendicular magnetic recording layer in the magnetic recording medium of the invention may comprise either a single magnetic layer or two or more magnetic layers. The single magnetic layer or at least one of the magnetic layers comprises ferromagnetic crystal grains which are predominantly comprised of cobalt and further comprise ruthenium, and further comprising grain boundaries comprised of an oxide. When the perpendicular magnetic recording layer comprises two or more magnetic layers, the magnetic layers may comprise different kinds of ferromagnetic crystal grains and different kinds of oxides. The ferromagnetic crystal grains in at least one of the magnetic layers are predominantly comprised of cobalt and further comprise ruthenium, and the ferromagnetic crystal grains in the other magnetic layer are preferably predominantly comprised of cobalt but may or may not comprise ruthenium.

When the perpendicular magnetic recording layer comprises two or more magnetic layers, the total thickness of the magnetic layers is preferably in the range of 2 nm to 40 nm.

The perpendicular magnetic recording medium according to the present invention can be produced by forming the respective layers thereof by sputtering target materials for forming the respective layers.

A target ferromagnetic material for forming the ferromagnetic crystal grains in the perpendicular magnetic recording layer is selected from ferromagnetic alloys comprising cobalt as an essential ingredient and optionally further comprising ruthenium. The ferromagnetic alloys preferably further comprise chromium. As specific examples of the ferromagnetic alloys, there can be mentioned cobalt-based alloys such as CoCr, CoCrPt, CoCrPtRu, CoCrPtB, CoCrPtRuB, CoCrPtB—X, CoCrPtRuB—X, CoCrPtB—X—Y and CoCrPtRuB—X—Y (wherein X and Y represent oxides).

In the case when Ru₂O is used as a target oxide material used for forming the oxide for grain boundaries in the perpendicular magnetic recording layer, a target ferromagnetic material may or may not contain ruthenium, which depends upon the sputtering conditions. When a target ferromagnetic material not containing ruthenium and oxide material containing Ru₂O are used, it is important that the target ferromagnetic material is selected from cobalt alloys having added therein an additional element exhibiting higher affinity with oxygen than the affinity of ruthenium with oxygen. Such additional element includes, for example, Cr, B, Ti, Ta and Cu.

Energy of sputtering particles is generally larger than the bond energy of a metal oxide. Therefore, it is presumed that, when a metal oxide-containing alloy target is sputtered, the metal oxide is dissociated into an oxygen atom and a metal atom, and, when or after the thus-emitted atoms reach a substrate, the metal atom is oxidized to give again an oxide.

When oxides are formed from elements having different affinities for oxygen, an element having a high affinity for oxygen is preferentially oxidized than an element having a poor affinity for oxygen. The affinity for oxygen is expressed by the bond energy between an element and oxygen. As the bond energy becomes larger, the oxide of the element becomes more stable, namely, the element is more easily oxidized.

As seen from the above-mentioned phenomenon, it is presumed that, when a ruthenium oxide-containing alloy target is sputtered, a metal element having a better affinity for oxygen than the affinity of ruthenium for oxygen can preferentially be oxidized. For example, the affinity of chromium for oxygen is larger than the affinity of ruthenium for oxygen, and therefore, when a cobalt-based ferromagnetic alloy having added therein chromium and ruthenium oxide is sputtered, chromium would be preferentially oxidized to be thereby deposited as chromium oxide to form crystal grain boundaries, and ruthenium would form as a metal a solid solution with the ferromagnetic alloy. This phenomenon can be confirmed by analyzing the chemically bound state and segregated state of the metal elements by X-ray photoelectron spectroscopy (XPS) and energy dispersive X-ray spectroscopy (EDS).

Due to the above-mentioned phenomenon, when a cobalt-based ferromagnetic alloy containing ruthenium oxide is sputtered, a resulting ferromagnetic crystal grains contain ruthenium. This result is similar to the case when a cobalt-based ferromagnetic alloy containing ruthenium metal is sputtered. Thus, under such film-forming conditions, the desired granular structure comprising cobalt-based ferromagnetic crystal grains containing ruthenium, and grain boundaries comprised of an oxide can be obtained whether a cobalt-based alloy target material contains ruthenium as an element in the alloy itself or as ruthenium oxide added therein.

In a perpendicular magnetic recording layer having a granular structure, the width of grain boundaries surrounding magnetic crystal grains and the size of magnetic crystal grains vary, and thus, the recording-reproducing characteristics vary, depending upon the particular kind of oxide constituting the grain boundaries. In the case when an oxide present in the granular structure is not easily subject to segregation from the magnetic crystal grains, the oxide tends to remain within the magnetic crystal grains, which gives a baneful influence on the crystal orientation and leads to deterioration of the magnetic properties.

It can be evaluated by the full width at half maximum Δ(delta)θ50 of a rocking curve whether the crystalline c-axis ([002] axis) in the magnetic recording layer is arranged in perpendicular to the substrate surface of the crystals with minimized disturbance, or not. The full width at half maximum Δθ50 of a rocking curve is determined as follows. A magnetic recording layer formed on a substrate is analyzed by X-ray diffractometry, i.e., the crystal plane which is parallel to the substrate surface is analyzed by scanning the incident angle of X-ray to observe diffraction peaks corresponding to the crystal plane. In the perpendicular magnetic recording medium comprising a cobalt-based alloy magnetic material, crystal orientation occurs so that the direction of the c-axis [002] of the hcp structure is perpendicular to the substrate surface, therefore, peaks attributed to the (002) crystal plane are observed. Then the optical system is swung relative to the substrate surface while a Bragg angle diffracting the (002) crystal plane is maintained. The diffraction intensity of the (002) crystal plane relative to the angle at which the optical system is inclined is plotted to draw a rocking curve with a center at a swung angle of zero degree. If the (002) crystal plane is in parallel with the substrate surface, a rocking curve with a sharp shape is obtained. In contrast, if the (002) crystal plane is broadly distributed, a rocking curve with a broadly widened shape is obtained. Thus, the crystal orientation in the perpendicular magnetic recording medium can be evaluated on the basis of the full width at half maximum Δ(delta)θ50 of the rocking curve.

The magnetic recording layer of the perpendicular magnetic recording medium according to the present invention has at least one magnetic layer having a granular structure comprising cobalt-based ferromagnetic crystal grains comprising ruthenium and grain boundaries comprised of an oxide, and therefore, the magnetic crystal grains are smaller and the full width at half maximum Δθ50 of the magnetic recording layer in the perpendicular magnetic recording medium is smaller than those of the conventional magnetic recording layer not containing ruthenium.

In the magnetic recording layer having a granular structure, the grain diameter and the crystal orientation influence on the width of oxide grain boundaries segregated on magnetic crystal grains, and consequently influence on the recording reproducing characteristics.

The respective layers in the perpendicular magnetic recording medium according to the present invention are usually formed by a DC magnetron sputtering method or an RF sputtering method.

Imposition of RF bias, DC bias, pulse DC or pulse DC bias can be adopted for sputtering. An inert gas such as, for example, argon can be used as sputtering gas, to which O₂ gas, H₂O or N₂ gas may be added. The pressure of sputtering gas is appropriately chosen for the respective layers so as to give layers with the desired characteristics, but, the pressure is usually controlled in the range of approximately 0.1 to 30 Pa. An appropriate pressure can be determined depending upon the particular magnetic characteristics of magnetic recording medium.

An overcoat is provided so as to protect the magnetic recording medium from being damaged by the contact thereof with a head. The overcoat includes, for example, a carbon layer and a SiO₂ layer. A carbon layer is widely used. The overcoat can be formed by, for example, a sputtering method or a plasma CVD method. A plasma CVD method including a magnetron plasma CVD method is popularly used in recent years.

The thickness of the overcoat is usually in the range of approximately 1 nm to 10 nm, preferably 2 nm to 6 nm and more preferably 2 nm to 4 nm.

The constitution of an example of the magnetic recording-reproducing apparatus according to the present invention is illustrated in FIG. 2. The magnetic recording-reproducing apparatus of the present invention comprises, in combination, the magnetic recording medium 10 as illustrated in FIG. 1; a driving part 11 for driving the magnetic recording medium 10 in the circumferential recording direction; a magnetic head 12 for recording an information in the magnetic recording medium 10 and reproducing the information from the medium 10; a head-driving part 13 for moving the magnetic head 12 in a relative motion to the magnetic recording medium 10; and a recording-and-reproducing signal treating means 14. The recording-and-reproducing signal treating means 14 has a function of transmitting signal from the outside to the magnetic head 12, and transmitting the reproduced output signal from the magnetic head 12 to the outside.

As the magnetic head 12 provided in the magnetic recording reproducing apparatus according to the present invention, there can be used a magnetic head provided with a reproduction element suitable for high-magnetic recording density, which includes a magneto-resistance (MR) element exhibiting an anisotropic magnetic resistance (AMR) effect, a GMR element exhibiting a giant magneto-resistance (GMR) effect and a TuMR element exhibiting a tunneling magneto-resistance effect.

### EXAMPLES

The invention will now be described specifically by the following examples.

### Example 1

### Comparative Example 1

A glass substrate for HD was placed in a vacuum chamber and the chamber was evacuated to a reduced pressure of below 1.0×10⁻⁵ Pa. A soft magnetic layer comprised of CoNbZr and having a thickness of 50 nm was formed on the glass substrate, and then an under layer comprised of NiFe with a fcc structure and having a thickness of 5 nm was formed on the soft magnetic layer. The formation of the soft magnetic layer and the under layer was carried out by a sputtering method at a reduced pressure of 0.6 Pa in an argon atmosphere. An intermediate layer comprised of Ru was formed on the under layer by a sputtering method in an argon atmosphere in two stages, that is, a Ru layer with a thickness of 10 nm was formed at a reduced pressure of 0.6 Pa in a first stage, and further a Ru layer with a thickness of 10 nm was formed at a reduced pressure of 10 Pa in a second stage.

A magnetic recording layer with a thickness of 10 nm was formed on the intermediate layer by sputtering at a reduced pressure of 2 Pa in an argon atmosphere. The composition of the magnetic recording layers formed according to the present invention in Example 1-1 trough Example 1-11 was as follows.

Example 1-1, 90(Co12Cr18Pt3Ru)-10(SiO₂)

Example 1-2, 90(Co12Cr18Pt3Ru)-10(Cr₂O₃)

Example 1-3, 90(Co12Cr18Pt3Ru)-10(RuO₂)

Example 1-4, 90(Co12Cr18Pt3Ru)-10(TiO₂)

Example 1-5, 90(Co12Cr18Pt3Ru)-10(WO₃)

Example 1-6, 90(Co12Cr18Pt3Ru)-10(WO₂)

Example 1-7, 90(Co12Cr18Pt3Ru)-10(Al₂O₃)

Example 1-8, 90(Co12Cr18Pt3Ru)-10(Ta₂O₅)

Example 1-9, 90(Co12Cr18Pt3Ru)-3(SiO₂)-7(TiO₂)

Example 1-10, 90(Co12Cr18Pt3Ru)-2(SiO₂)-8(RuO₂)

Example 1-11, 90(Co12Cr18Pt3Ru)-6(TiO₂)-4(Ta₂O₅)

For comparison, a magnetic recording layer with a thickness of 10 nm was formed on the intermediate layer at a reduced pressure of 2 Pa in an argon atmosphere by substantially the same procedure as mentioned above in Comparative Example 1-1 through Comparative Example 1-3, except that the composition thereof was changed as follows.

Comparative Example 1-1, 90(Co12Cr18Pt)-10(SiO₂)

Comparative Example 1-2, 90(Co12Cr18Pt)-10(TiO₂)

Comparative Example 1-3, 90(Co12Cr18Pt)-3(SiO₂)-7(TiO₂)

Note, the numerals “90” and “10” which occur immediately before the two parentheses in the formula 90(Co12Cr18Pt3Ru)-10(SiO₂) in Example 1-1 refer to a proportion by mole % of the ferromagnetic crystal grains and the oxide, respectively. The numerals “12”, “18” and “3” which occur within the first parenthesis “(Co12Cr18Pt3Ru)” refer to that the relative amounts of Cr, Pt and Ru are 12 atomic %, 18 atomic % and 3 atomic %, respectively, and the amount of Co is the balance. This expedient expression applies to the compositions of the ferromagnetic crystal grains in the other Examples and Comparative Examples.

A thin carbon film as an overcoat was formed on each of the magnetic recording layers in the above examples and comparative examples to give a perpendicular magnetic recording medium.

Each of the perpendicular magnetic recording mediums made in Examples 1-1 through 1-11 and Comparative Examples 1-1, 1-2 and 1-3 was coated with a lubricant, and recording/reproducing characteristics thereof (i.e., signal-to-noise ratio SNR) were evaluated using Read-Write Analyzer 1632 and Spin Stand S1701MP, which are available from GUZIK, US. Further, magnetostatic property (i.e., coercive force Hc) of the same perpendicular magnetic recording mediums was evaluated using a Kerr tester. Crystal orientation of the ferromagnetic cobalt-based alloy crystal grains in each magnetic recording layer was evaluated by the c-axis orientation dispersion (Δθ50) using X-ray diffractometry. Average crystal grain diameter was measured on a plain TEM image of the magnetic recording layer. These parameters are widely used for evaluating the characteristics of perpendicular magnetic recording mediums. The evaluation results are shown in Table 1.

TABLE 1

| | | | | Average | |
|---|---|---|---|---|---|
| | Composition of | | | Grain | Co [symbol] |
| | Magnetic Recording | SNR | Hc | Diameter | θ50 |
| Sample | Layer | (dB) | (Oe) | (nm) | (°) |
| Example | 90(Co12Cr18Pt3Ru)—10(SiO₂) | 16.55 | 4702 | 7.2 | 3.50 |
| 1-1 | | | | | |
| Example | 90(Co12Cr18Pt3Ru)—10(Cr₂O₃) | 16.82 | 4682 | 7.2 | 3.51 |
| 1-2 | | | | | |
| Example | 90(Co12Cr18Pt3Ru)—10(RuO₂) | 16.64 | 4681 | Sample | 3.49 |
| 1-3 | | | | | |
| Example | 90(Co12Cr18Pt3Ru)—10(TiO₂) | 16.52 | 4673 | 7.2 | 3.46 |
| 1-4 | | | | | |
| Example | 90(Co12Cr18Pt3Ru)—10(WO₃) | 16.65 | 4679 | 7.5 | 3.51 |
| 1-5 | | | | | |
| Example | 90(Co12Cr18Pt3Ru)—10(WO₂) | 16.61 | 4736 | 7.4 | 3.38 |
| 1-6 | | | | | |
| Example | 90(Co12Cr18Pt3Ru)—10(Al₂O₃) | 16.57 | 4680 | 7.3 | 3.34 |
| 1-7 | | | | | |
| Example | 90(Co12Cr18Pt3Ru)—10(Ta₂O₅) | 16.72 | 4761 | 7.3 | 3.47 |
| 1-8 | | | | | |
| Example | 90(Co12Cr18Pt3Ru)—3(SiO₂)—7(TiO₂) | 16.68 | 4566 | 7.2 | 3.54 |
| 1-9 | | | | | |
| Example | 90(Co12Cr18Pt3Ru)—2(SiO₂)—8(RuO₂) | 16.58 | 4673 | 7.5 | 3.42 |
| 1-10 | | | | | |
| Example | 90(Co12Cr18Pt3Ru)—6(TiO₂)—4(Ta₂O₅) | 16.58 | 4665 | 7.4 | 3.35 |
| 1-11 | | | | | |
| Co. Ex. | 90(Co12Cr18Pt)—10(SiO₂) | 15.38 | 4530 | 8.5 | 4.23 |
| 1-1 | | | | | |
| Co. Ex. | 90(Co12Cr18Pt)—10(TiO₂) | 15.55 | 4523 | 8.3 | 4.25 |
| 1-2 | | | | | |
| Co. Ex. | 90(Co12Cr18Pt)—3(SiO₂)—7(TiO₂) | 15.51 | 4513 | 8.3 | 4.15 |
| 1-3 | | | | | |

As seen from Table 1, the incorporation of ruthenium in the ferromagnetic crystal grains reduces diameter of magnetic crystal grains and enhances crystal orientation (Examples 1-1 through 1-11), which is in contrast to the case when ruthenium is not incorporated in the ferromagnetic crystal grains (Comparative Examples 1-1, 1-2 and 1-3). Thus, ruthenium incorporated in the ferromagnetic crystal grains has a function of improving the magnetostatic characteristics and electromagnetic conversion characteristics to an extent greater than that achieved by the ferromagnetic crystal grains having no ruthenium incorporated therein. It is presumed that this is due to the fact that an oxide exhibits high segregation to form grain boundaries as compared with the ferromagnetic crystal grains having no ruthenium incorporated therein. As seen from Examples 1-9 to 1-11, the above-mentioned benefits of the ferromagnetic crystal grains having ruthenium incorporated therein can be obtained even when two or more kinds of oxides are used in combination with the ferromagnetic crystal grains.

### Example 2

### Comparative Example 2

Magnetic recording mediums were produced by the same procedures as mentioned in Example 1 and Comparative Example 1, wherein a non-magnetic amorphous material Cr50Ti layer with a thickness of 20 nm was formed instead of the soft magnetic CoNBZr layer on the glass substrate at a reduced pressure of 0.8 Pa. The Cr50Ti layer is completely free of magnetization in contrast to the soft magnetic layer, and thus, the formation of the non-magnetic amorphous material Cr50Ti layer was conducted for the purpose of vibrating sample magnetrometer (VSM) measurement and torque measurement for evaluating saturation magnetization Ms and perpendicular magnetic anisotropy Ku.

The NiFe under layer, the Ru intermediate layer, the magnetic recording layer having the following composition and the carbon overcoat were formed in this order on the non-magnetic amorphous Cr50Ti layer by the same procedures and under the same conditions as adopted in the above-mentioned examples and comparative examples. All procedures and other conditions remained the same.

Example 2-1, 90(Co12Cr18Pt3Ru)-10(SiO₂)

Example 2-2, 90(Co12Cr18Pt3Ru)-10(WO₃)

Comparative Example 2-1, 90(Co12Cr18Pt)-10(SiO₂)

Comparative Example 2-2, 90(Co12Cr18Pt)-10(WO₃)

Using the magnetic recording mediums, saturation magnetization Ms (emu/cm³) and perpendicular magnetic anisotropy Ku (erg/cm³) of each magnetic recording layer were measured by a vibrating sample magnetometer (VSM) measurement and a torque measurement. The test results are shown in Table 2.

TABLE 2

| | Composition of | Ms | Ku |
|---|---|---|---|
| Sample | Magnetic Recording Layer | (emu/cm³) | (10⁶ erg/cm³) |
| Example | 90(Co12Cr18Pt3Ru)—10(SiO₂) | 630 | 6.4 |
| 2-1 | | | |
| Example | 90(Co12Cr18Pt3Ru)—10(WO₃) | 622 | 6.3 |
| 2-2 | | | |
| Co. Ex. | 90(Co12Cr18Pt)—10(SiO₂) | 660 | 5.3 |
| 2-1 | | | |
| Co. Ex. | 90(Co12Cr18Pt)—10(WO₃) | 651 | 5.4 |
| 2-1 | | | |

As seen from Table 2, the saturated magnetization of the magnetic recording medium having a magnetic recording layer comprising ruthenium-containing ferromagnetic crystal grains in Examples 2-1 and 2-2 is only several % less than that of the magnetic recording medium having a magnetic recording layer comprising ferromagnetic crystal grains containing no ruthenium in Comparative Examples 2-1 and 2-2. In contrast, the perpendicular magnetic anisotropy of the magnetic recording layer comprising ruthenium-containing ferromagnetic crystal grains in Examples 2-1 and 2-2 is larger than that of the magnetic recording layer comprising ferromagnetic crystal grains containing no ruthenium in Comparative Examples 2-1 and 2-2. This fact would be foreseen from the fact that the magnetic recording layer comprising ruthenium-containing ferromagnetic crystal grains in Examples 2-1 and 2-2 has high crystal orientation and high coercive force as compared with those of the magnetic recording layer comprising ferromagnetic crystal grains containing no ruthenium in Comparative Examples 2-1 and 2-2. This beneficial effect is presumed to be due to the fact that the high magnetic anisotropy of the cobalt-based magnetic crystal grains can be maintained to the largest extent by incorporating ruthenium having a hexagonal close-packed (hcp) structure in the cobalt-based magnetic crystal grains also having a hcp structure.

### Example 3

### Comparative Example 3

By the same procedures as mentioned in Example 1, a soft magnetic layer, an under layer, an intermediate layer, a magnetic recording layer and a carbon overcoat were formed in this order on a glass substrate to give a magnetic recording medium wherein each of the magnetic recording layers having the following compositions and having a thickness of 12 nm was formed by sputtering at a reduced pressure of 2 Pa in an argon atmosphere. All other procedures and conditions remained the same.

Example 3-1, 90(Co12Cr18Pt1Ru)-10(SiO₂)

Example 3-2, 90(Co12Cr18Pt5Ru)-10(SiO₂)

Example 3-3, 90(Co12Cr18Pt10Ru)-10(SiO₂)

Example 3-4, 90(Co12Cr18Pt15Ru)-10(SiO₂)

For comparison, a comparative magnetic recording medium was produced by the same procedures as mentioned above except that, instead of the magnetic recording layer comprising ruthenium-containing ferromagnetic crystal grains, a magnetic recording layer having the following composition and having a thickness of 10 nm was formed by sputtering at a reduced pressure of 2 Pa in an argon atmosphere. All other procedures and conditions remained the same.

Comparative Example 3-1, 90(Co12Cr18Pt)-10(SiO₂)

Using the above-mentioned magnetic recording mediums, signal-to-noise ratio (SNR), coercive force (Hc), c-axis orientation dispersion (Δθ50) of the cobalt-based magnetic crystal grains and average grain diameter of the cobalt-based magnetic crystal grains were evaluated. The test results are shown in Table 3.

TABLE 3

| | | | | Average | |
|---|---|---|---|---|---|
| | Composition of | | | Grain | Co [symbol] |
| | Magnetic Recording | | | Diameter | θ50 |
| Sample | Layer | SNR (dB) | Hc (Oe) | (nm) | (°) |
| Example | 90(Co12Cr18Pt1Ru)—10(SiO₂) | 16.46 | 4702 | 7.5 | 3.40 |
| 3-1 | | | | | |
| Example | 90(Co12Cr18Pt5Ru)—10(SiO₂) | 16.50 | 4682 | 7.3 | 3.36 |
| 3-2 | | | | | |
| Example | 90(Co12Cr18Pt10Ru)—10(SiO₂) | 16.41 | 4663 | 7.4 | 3.38 |
| 3-3 | | | | | |
| Example | 90(Co12Cr18Pt15Ru)—10(SiO₂) | 16.33 | 4673 | 7.5 | 3.40 |
| 3-4 | | | | | |
| Co. Ex. | 90(Co12Cr18Pt)—10(SiO₂) | 15.38 | 4530 | 8.5 | 4.23 |
| 3-1 | | | | | |

As seen from Table 3, in the case when the amount of ruthenium in the magnetic crystal grains is in the range of 1 to 15 atomic % (Examples 3-1 to 3-4), the diameter of magnetic crystal grains is small and the crystal orientation is high, to the desired extent, and thus, the magnetostatic characteristic and electromagnetic conversion characteristic are improved, as compared with the case when ruthenium is not contained in the magnetic crystal grains (Comparative Example 3-1). Thus, it will be seen that the amount of ruthenium in the magnetic crystal grains is preferably in the range of 1 to 15 atomic %.

### Example 4

### Comparative Example 4

By the same procedures as mentioned in Example 1, a soft magnetic layer, an under layer, an intermediate layer, a magnetic recording layer and a carbon overcoat were formed in this order on a glass substrate to give a magnetic recording medium wherein each of the magnetic recording layers having the following compositions and having a thickness of 12 nm were formed by sputtering at a reduced pressure of 2 Pa in an argon atmosphere. All other procedures and conditions remained the same.

Example 4-1, 98(Co12Cr18Pt3Ru)-2(SiO₂)

Example 4-2, 96(Co12Cr18Pt3Ru)-4(SiO₂)

Example 4-3, 92(Co12Cr18Pt3Ru)-8(SiO₂)

Example 4-4, 88(Co12Cr18Pt3Ru)-12(SiO₂)

Example 4-5, 84(Co12Cr18Pt3Ru)-16(SiO₂)

Example 4-6, 80(Co12Cr18Pt3Ru)-20 (SiO₂)

For comparison, a comparative magnetic recording medium was produced by the same procedures as mentioned above except that a magnetic recording layer having the following composition and having a thickness of 10 nm was formed by sputtering at a reduced pressure of 2 Pa in an argon atmosphere. All other procedures and conditions remained the same.

Comparative Example 4-1, Co12Cr18Pt3Ru

Using the above-mentioned magnetic recording mediums, signal-to-noise ratio (SNR), coercive force (Hc), c-axis orientation dispersion (Δθ50) of the cobalt-based magnetic crystal grains and average grain diameter of the cobalt-based magnetic crystal grains were evaluated. The test results are shown in Table 4.

TABLE 4

| | | | | Average | |
|---|---|---|---|---|---|
| | Composition of | | | Grain | Co [symbol] |
| | Magnetic Recording | | | Diameter | θ50 |
| Sample | Layer | SNR (dB) | Hc (Oe) | (nm) | (°) |
| Example | 98(Co12Cr18Pt3Ru)—2(SiO₂) | 16.40 | 4685 | 7.9 | 3.50 |
| 4-1 | | | | | |
| Example | 96(Co12Cr18Pt3Ru)—4(SiO₂) | 16.30 | 4702 | 7.8 | 3.55 |
| 4-2 | | | | | |
| Example | 92(Co12Cr18Pt3Ru)—8(SiO₂) | 16.50 | 4682 | 7.6 | 3.51 |
| 4-3 | | | | | |
| Example | 88(Co12Cr18Pt3Ru)—12(SiO₂) | 16.48 | 4673 | 8.1 | 3.41 |
| 4-4 | | | | | |
| Example | 84(Co12Cr18Pt3Ru)—16(SiO₂) | 16.42 | 4673 | 7.7 | 3.55 |
| 4-5 | | | | | |
| Example | 80(Co12Cr18Pt3Ru)—20(SiO₂) | 16.33 | 4652 | 7.4 | 3.76 |
| 4-6 | | | | | |
| Co. Ex. | Co12Cr18Pt3Ru | 10.50 | 2265 | 12.3 | 3.21 |
| 4-7 | | | | | |

As seen from Table 4, in the case when the amount of the oxide in the magnetic recording layer is in the range of 2% to 20% by mole (Examples 4-1 to 4-6), the diameter of magnetic crystal grains is small and the crystal orientation is high, and thus, the magnetostatic characteristic and electromagnetic conversion characteristic are improved. In contrast, in the case when the oxide is not contained in the magnetic recording layer (Comparative Example 4-1), the diameter of magnetic crystal grains is large and thus the crystal orientation dispersion is better than those in Examples 4-1 to 4-6, but, the exchange coupling among magnetic crystal grains is strong and thus the magnetostatic characteristics are poor, the signal-to-noise ratio is low, and the reduction of SNR is at least 5 dB.

### Example 5

### Comparative Example 5

By the same procedures as mentioned in Example 1, a soft magnetic layer, an under layer, an intermediate layer, a magnetic recording layer and a carbon overcoat were formed in this order on a glass substrate to give a magnetic recording medium wherein the magnetic recording layer was formed in two stages. That is, a first magnetic layer, and then a second magnetic layer were formed by sputtering at a reduced pressure of 2 Pa in an argon atmosphere. The total thickness of the magnetic layers was 12 nm. The compositions of the first and second magnetic layers were selected from the following three compositions as shown in Table 5. All other procedures and conditions remained the same.

90(Co12Cr18Pt3Ru)-6(SiO₂)-4(RuO₂)

90(Co10Cr20Pt)-10(SiO₂)

90(Co10Cr20Pt)-10(TiO₂)

For comparison, comparative magnetic recording mediums were produced by the same procedures as mentioned above except that a single magnetic recording layer having the following composition and having a thickness of 10 nm was formed by sputtering at a reduced pressure of 2 Pa in an argon atmosphere, instead of the first and second magnetic layers. All other procedures and conditions remained the same.

Comparative Example 5-1, 90(Co10Cr20Pt)-10(SiO₂)

Comparative Example 5-2, 90(Co10Cr20Pt)-10(TiO₂)

Using the above-mentioned magnetic recording mediums, signal-to-noise ratio (SNR), coercive force (Hc), c-axis orientation dispersion (Δθ50) of the cobalt-based magnetic crystal grains and average grain diameter of the cobalt-based magnetic crystal grains were evaluated. The test results are shown in Table 5.

TABLE 5

| | | | | | Av. | |
|---|---|---|---|---|---|---|
| | Composition of | Composition of | | | Grain | Co [symbol] |
| | First Magnetic | Second Magnetic | SNR | Hc | Diameter | θ50 |
| Sample | Recording Layer | Recording Layer | (dB) | (Oe) | (nm) | (°) |
| Ex. | 90(Co12Cr18Pt3Ru)—6(SiO₂)—4(RuO₂) | 90(Co10Cr20Pt)—10(SiO₂) | 16.53 | 4783 | 7.6 | 3.48 |
| 5-1 | | | | | | |
| Ex. | 90(Co12Cr18Pt3Ru)—6(SiO₂)—4(RuO₂) | 90(Co10Cr20Pt)—10(TiO₂) | 16.65 | 4785 | 7.3 | 3.55 |
| 5-2 | | | | | | |
| Ex. | 90(Co10Cr20Pt)—10(SiO₂) | 90(Co12Cr—18Pt3Ru)—6(SiO₂)—4(RuO₂) | 16.72 | 4792 | 7.3 | 3.32 |
| 5-3 | | | | | | |
| Ex. | 90(Co10Cr20Pt)—10(TiO₂) | 90(Co12Cr—18Pt3Ru)—6(SiO₂)—4(RuO₂) | 16.67 | 4752 | 7.4 | 3.46 |
| 5-4 | | | | | | |

| | | | | | |
|---|---|---|---|---|---|
| Co. | 90(Co10Cr20Pt)—10(SiO₂) | 15.31 | 4554 | 8.3 | 4.06 |
| Ex. | | | | | |
| 5-1 | | | | | |
| Co. | 90(Co10Cr20Pt)—10(TiO₂) | 15.24 | 4481 | 8.2 | 4.13 |
| Ex. | | | | | |
| 5-2 | | | | | |

As seen from Table 5, in the case when at least one of the first and second magnetic layers is a magnetic recording layer comprising ruthenium-containing magnetic crystal grains, the diameter of magnetic crystal grains can be reduced and the crystal orientation is enhanced, and thus, the magnetostatic characteristics and electromagnetic conversion characteristics are improved.

### Example 6

### Comparative Example 6

By the same procedures as mentioned in Example 1, a soft magnetic layer, an under layer, an intermediate layer, a magnetic recording layer and a carbon overcoat were formed in this order on a glass substrate to give a magnetic recording medium wherein the magnetic recording layer was formed by sputtering a target material having the following composition at a reduced pressure of 2 Pa in an argon atmosphere. The magnetic recording layer had a thickness of 12 nm. All other procedures and conditions remained the same.

Example 6-1, 90(Co12Cr18Pt)-10(RuO₂)

Example 6-2, 90(Co12Cr18Pt)-7(TiO₂)-3(RuO₂)

Example 6-3, 92(Co12Cr18Pt4Ti)-4(SiO₂)-4(RuO₂)

For comparison, a comparative magnetic recording medium was produced by the same procedures as mentioned above except that a magnetic recording layer having a thickness of 10 nm was formed by sputtering a target material having the following composition at a reduced pressure of 2 Pa in an argon atmosphere. All other procedures and conditions remained the same.

Comparative Example 6-1, 90(Co12Cr18Pt)-10(SiO₂)

Comparative Example 6-2, 90(Co12Cr18Pt4Ti)-6(SiO₂)-4(Cr₂O₃)

Using the above-mentioned magnetic recording mediums, signal-to-noise ratio (SNR), coercive force (Hc), c-axis orientation dispersion (Δθ50) of the cobalt-based magnetic crystal grains and average grain diameter of the cobalt-based magnetic crystal grains were evaluated. The test results are shown in Table 6.

TABLE 6

| | | | | | Av. | |
|---|---|---|---|---|---|---|
| | | Composition of | | | Grain | Co [symbol] |
| | Composition of | Magnetic | SNR | Hc | Diameter | θ50 |
| Sample | Target Material | Recording Layer | (dB) | (Oe) | (nm) | (°) |
| Ex. | 90(Co12Cr—18Pt)—10(RuO₂) | 94(Co7Cr—18Pt6Ru)—4(RuO₂)—2(Cr₂O₃) | 16.63 | 4753 | 7.2 | 3.29 |
| 6-1 | | | | | | |
| Ex. | 90(Co12Cr—18Pt)—7(TiO₂)—3(RuO₂) | 92(Co10Cr—18Pt3Ru)—7(TiO₂)—1(Cr₂O₃) | 16.75 | 4775 | 7.3 | 3.41 |
| 6-2 | | | | | | |
| Ex. | 92(Co12Cr—18Pt4Ti)—6(SiO₂)—4(RuO₂) | 92(Co12Cr—18Pt4Ru)—6(SiO₂)—4(TiO₂) | 16.65 | 4762 | 7.3 | 3.32 |
| 6-3 | | | | | | |
| Co. Ex. | 90(Co12Cr—18Pt)—10(SiO₂) | Same as | 15.38 | 4530 | 8.5 | 4.23 |
| 6-1 | | Composition of | | | | |
| | | Target Material | | | | |
| Co. Ex. | 90(Co12Cr—18Pt4Ti)—6(SiO₂)—4(Cr₂O₃) | Same as | 15.31 | 4402 | 8.4 | 4.46 |
| 6-2 | | Composition of | | | | |
| | | Target Material | | | | |

As seen from Table 6, even in the case when a target material for forming ferromagnetic crystal grains containing no ruthenium is used, a magnetic recording layer comprising ruthenium-containing ferromagnetic crystal grains can be formed by sputtering, if ruthenium oxide is used as a target material in combination with the target material for forming ferromagnetic crystal grains. The thus-prepared magnetic recording layer comprises magnetic crystal grains having a reduced grain diameter and the resulting magnetic recording medium exhibits improved recording/reproducing characteristics. It is presumed that ruthenium oxide is dissociated into an oxygen atom and a ruthenium atom, and, the oxygen atom is bonded with a metal having a high affinity with oxygen, such as chromium or titanium, and the ruthenium metal is taken into the ferromagnetic crystal grains.

### INDUSTRIAL APPLICABILITY

The perpendicular recording medium according to the present invention is characterized as having an improved crystalline structure of the magnetic recording layer, more specifically, a hexagonal close-packed (hcp) structure, wherein its crystal c-axes are orientated in the perpendicular direction with minimized disturbance in angle, and ferromagnetic crystal grains in the magnetic recording layer have an extremely small average grain diameter. Therefore the perpendicular recording medium exhibits improved recording density characteristics.

Utilizing the beneficial characteristics, the perpendicular magnetic recording medium according to the present invention is suitable for a magnetic recording/reproducing apparatus, for example, a magnetic disk apparatus.

The perpendicular magnetic recording medium is expected to have a more enhanced recording density, and is also suitable for new perpendicular recording media such as, for example, ECC media, discrete track media and pattern media.

1. A perpendicular magnetic recording medium comprising at least a soft magnetic layer, an under layer, an intermediate layer and a perpendicular magnetic recording layer, which are formed on a non-magnetic substrate, characterized in that said perpendicular magnetic recording layer is comprised of at least one magnetic layer, which magnetic layer or at least one of which magnetic layers comprises ferromagnetic crystal grains predominantly comprised of cobalt and grain boundaries comprised of an oxide, wherein said ferromagnetic crystal grains further comprise ruthenium.

2. The perpendicular magnetic recording medium according to claim 1, wherein the content of ruthenium in the ferromagnetic crystal grains is in the range of 1 atomic % to 15 atomic %.

3. The perpendicular magnetic recording medium according to claim 1, wherein the oxide contained in the magnetic layer or layers comprising the ferromagnetic crystal grains and the grain boundaries comprised of an oxide is at least one oxide selected from the group consisting of oxides of Si, Ti, Ta, Cr, Al, W, Nb and Ru.

4. The perpendicular magnetic recording medium according to claim 1, wherein the total amount of the oxide contained in the magnetic layer or layers comprising the ferromagnetic crystal grains and the grain boundaries comprised of an oxide is in the range of 2% to 20% by mole.

5. The perpendicular magnetic recording medium according to claim 1, wherein the ferromagnetic crystal grains have an average grain diameter in the range of 3 nm to 12 nm.

6. The perpendicular magnetic recording medium according to claim 1, wherein the thickness of the magnetic layer or each of the magnetic layers, which comprises the ferromagnetic crystal grains and the grain boundaries comprised of an oxide, is in the range of 1 nm to 20 nm; and the total thickness of the magnetic layers is in the range of 2 nm to 40 nm.

7. The perpendicular magnetic recording medium according to claim 1, wherein the soft magnetic layer has a soft magnetic non-crystalline or microcrystalline structure.

8. A process for producing the perpendicular magnetic recording medium as claimed in claim 1, which comprises a step of forming the perpendicular magnetic recording layer by sputtering a target material which comprises a ferromagnetic material comprising at least cobalt, and an oxide material, wherein at least one of the ferromagnetic material and the oxide material contains ruthenium.

9. A magnetic recording reproducing apparatus provided with a perpendicular magnetic recording medium and a magnetic head for recording and reproducing an information in the magnetic recording medium, characterized in that the perpendicular magnetic recording medium is the one as claimed in claim 1.
